(19) United States
(12) Patent Application Publication
(10) Pub. No.: US 2015/0162524 A1
(43) Pub. Date: Jun. 11, 2015

(54) SECONDARY FLUX PATH FOR MAGNETOSTRICTIVE CIRCUITS

(71) Applicant: Oscilla Power, Inc., Seattle, WA (US)

(72) Inventors: Balakrishnan G. Nair, Sandy, UT (US); Jeff Campbell, Spanish Fork, UT (US); Vinod Challa, Seattle, WA (US); Andrew Joseph Gill, Salt Lake City, UT (US)

(73) Assignee: Oscilla Power, Inc., Seattle, WA (US)

(21) Appl. No.: 14/533,998

(22) Filed: Nov. 5, 2014

Related U.S. Application Data
(60) Provisional application No. 61/900,193, filed on Nov. 5, 2013.
(60) Provisional application No. 61/944,470, filed on Feb. 25, 2014.

(51) Int. Cl. H01L 41/12

(52) U.S. Cl. CPC H01L 41/125

(57) ABSTRACT

An energy harvester generates electrical energy from mechanical energy using changing flux properties in primary and secondary flux paths. An apparatus includes at least two primary flux paths. The primary flux paths include at least one bias flux path configured to exhibit a change in a flux property in response to a change in an external load applied to the bias flux path. The secondary flux path is magnetically coupled to the primary flux paths. The secondary flux path is configured to experience alternating flux directions in response to the change in the flux property of the bias flux path. Electrical energy can be induced in a conductor as a result of the alternating flux direction in the secondary flux path.

### CROSS-REFERENCE TO RELATED APPLICATIONS

This application claims the benefit of U.S. Provisional Application No. 61/944,470 (Atty docket no. OSC-P027P), entitled “Secondary Flux Path for Magnetostrictive Circuits,” filed on Feb. 25, 2014, which is incorporated by reference herein in its entirety. This application also claims the benefit of U.S. Provisional Application No. 61/900,193 (Atty docket no. OSC-P025P), entitled “Utilizing Stiffness Adjusters in Conjunction with Pre-Compressed Magnetostrictive Materials,” filed on Nov. 5, 2013, which is incorporated by reference herein in its entirety.

### STATEMENT OF FEDERALLY SPONSORED RESEARCH

This invention was made with Government support under DE-SC0010232 awarded by the Department of Energy. The Government has certain rights to this invention.

### BACKGROUND

Electrical energy may be harvested from mechanical energy using magnetostrictive materials. Applying varying loads or forces to magnetostrictive materials imposes changes in strain of the magnetostrictive materials, which results in a change in magnetization or flux density of an associated magnetic field. The changes in the magnetic properties with the application of stress allow for the harvesting of electrical power from mechanical energy. This process is sometimes referred to as reverse magnetostriction.

Conventional energy harvesters that utilize magneto strictive materials in reverse magnetostriction typically use a coil to directly induce current from the magnetostrictive material and physical structure that experiences the stress or strain from the external force.

### SUMMARY

Embodiments of an energy harvester generate electrical energy from mechanical energy using changing flux properties in primary and secondary flux paths. At least one of the primary flux paths may include a magnetostrictive element. The primary flux paths also may include a permanent magnet as a source of magnetomotive force.

In one embodiment, an apparatus includes at least two primary flux paths. The primary flux paths include at least one bias flux path configured to exhibit a change in a flux property in response to a change in an external load applied to the bias flux path. The secondary flux path is magnetically coupled to the primary flux paths. The secondary flux path is configured to experience alternating flux directions in response to the change in the flux property of the bias flux path. Electrical energy can be induced in a conductor as a result of the alternating flux direction in the secondary flux path. Other embodiments of devices, systems, and methods are also described.

Other aspects and advantages of embodiments of the present invention will become apparent from the following detailed description, taken in conjunction with the accompanying drawings, illustrated by way of example of the principles of the invention.

### BRIEF DESCRIPTION OF THE DRAWINGS

FIG. 1A illustrates a schematic diagram of one embodiment of a magnetic circuit for implementation in a magnetostrictive electric power generator or other magnetostrictive device.

FIG. 1B illustrates a schematic diagram of one embodiment of a magnetostrictive electric power generator system 110 using the magnetic circuit 100 of FIG. 1A.

FIGS. 2A-C illustrate a schematic diagram of one embedment of a magnetostrictive generator assembly with a secondary flux path between two primary flux paths.

FIG. 3A illustrates another embodiment of magnetostrictive generator assembly that has a secondary flux path that is much longer than the primary flux paths.

FIG. 3B illustrates another embodiment of magnetostrictive generator or other magnetostrictive device that has multiple secondary flux paths in parallel with the primary flux paths.

FIG. 3C illustrates another embodiment of cantilevered magnetostrictive generator assembly that has a secondary flux path coupled to the primary flux paths.

FIGS. 4A-C illustrate a schematic diagram of the magnetostrictive generator assembly of FIGS. 2A-C with one embodiment of a hydraulic loading system 180.

FIG. 5A illustrates schematic waveforms to show stresses applied to an embodiment magnetostrictive rods.

FIG. 5B illustrates schematic waveforms to show the flux in the secondary flux path changing from a positive to a negative value, for a total change of approximately 2 Tesla.

FIGS. 6A and 6B illustrate alternative embodiments of schematic waveforms to depict relative flux changes in primary flux paths.

FIG. 7 illustrates a schematic diagram of one embodiment of magnetostrictive generator assembly that includes stiffness adjusters within a pre-compression zone.

FIG. 8 illustrates a schematic diagram of another embodiment of magnetostrictive generator assembly that includes stiffness adjusters outside of a pre-compression zone.

FIG. 9 depicts results from a stress ratio calculation using stiffness adjusters showing the changes in stress ratio with the addition of a stiffness adjuster.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Reference throughout this specification to “one embodiment,” “an embodiment,” or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

While many embodiments are described herein, at least some of the described embodiments facilitate increased power density from a magnetostrictive energy harvester or other power generator. In general, magnetostrictive energy harvesters operate on the principle of reverse magnetostriction to convert changes in mechanical stress on a magnetostrictive element into electrical energy induced in a coil or conductor. The power density of the induced electricity in the coil is based, at least in part, on the amount of magnetic flux change in the magnetostrictive element, which is a result of the change in mechanical stress on the magnetostrictive element.

Other magnetostrictive devices which may include without limitation sensors and actuators, may utilize reverse magnetostriction or conventional magnetostriction. In conventional magnetostriction, a change in applied magnetic field can be utilized to cause a change in strain and/or stress in at least one magnetostrictive element that comprises at least one magnetostrictive material.

Embodiments of a magnetostrictive energy harvester may have at least two primary flux paths and at least one secondary flux path. The secondary flux path is coupled to, but separate from, the primary flux paths. In general, a difference between the changing flux characteristics in the primary flux paths results in a flux change in the secondary flux path. Coils may be disposed near the primary flux path and/or the secondary flux path to carry the induced electricity in response to the changing magnetic flux in the corresponding flux path(s).

The primary flux paths may be categorized as “bias” flux paths or “reference” flux paths. A bias flux path is a primary flux path in which the flux changes originate, for example, due to an external mechanical force on a magnetostrictive element. In other words, the bias flux path has a variable magnetic reluctance. In contrast, a reference flux path is a primary flux path that has constant (or substantially constant) flux characteristics, or a static magnetic reluctance, except when the material of the reference flux path approaches a condition of magnetic saturation.

In one embodiment, the magnetostrictive energy harvester has two bias flux paths. Flux changes originate in the bias flux paths from changes in one or more external forces applied to or experienced by the bias flux paths. The changes in the external force(s) on the bias flux paths may fluctuate on a regular basis, semi-regular basis, or randomly. Also, where multiple external forces are present on separate magnetostrictive elements, the changes in the external forces may be symmetrical and/or synchronous. Alternatively, the external forces may be asynchronous and/or asymmetrical.

A difference between the changing flux characteristics in the bias flux paths results in a flux change in the secondary flux path that can induce current in a nearby electrical conductor such as a coil. In other words, when the flux characteristics of one or more bias flux paths changes, the flux characteristics of the coupled secondary flux path also changes. These changes in the flux characteristics of the coupled secondary flux path can be used to induce current in a nearby coil or conductor.

In another embodiment, the magnetostrictive energy harvester has one bias flux path and one reference flux path. Flux changes originate in the bias flux path from changes in one or more external forces experienced by the bias flux path. In contrast, the flux characteristics of the reference flux path remain unchanged. Rather, as the flux changes in the bias flux path relative to the static flux characteristics of the reference flux path, a difference between the relative flux characteristics results in a flux change in the secondary flux path that can induce current in the nearby electrical conductor.

In a more specific embodiment, the flux characteristics of the reference flux path are determined by the properties of the material used to implement the reference flux path. In some embodiments, the reference flux path is designed to have a magnetic flux that is intermediate within a range of the changing magnetic flux of the bias flux path. More specifically, the magnetic flux of the reference flux path may be approximately halfway between the minimum and maximum magnetic flux characteristics of the bias flux path during typical operation.

Alternatively, from the opposite perspective, the external forces on the bias flux path cause the magnetic flux characteristics (e.g., reluctance and/or permeability) of the bias flux path to oscillate above and below the static magnetic flux characteristics of the reference flux path. This relative difference between reluctance values of the two primary flux paths results in directional flux properties in the secondary flux path.

Furthermore, in some embodiments, a single external force may be converted into multiple external forces, with forces of opposite magnitude and/or direction conveyed to separate magnetostrictive elements. For example, an arrangement of one or more magnetostrictive elements may experience changes in an external force in a first direction, while another arrangement of one or more magnetostrictive elements experiences alternating changes in external force. In other words, the changes in the external force(s) are alternately applied to the different arrangements of magnetostrictive elements.

In some embodiments, the change in stress of one or more magnetostrictive elements results in a change in direction of the flux in at least one secondary flux path component. Each magnetostrictive element includes one or more magnetostrictive materials. Each magnetostrictive element is also part of a primary flux path. The secondary flux path component includes at least one magnetically permeable material. In one embodiment, the magnetically permeable material is a material having a relative permeability greater than 10.

In some embodiments, the change in flux in the primary and/or secondary flux paths can result in the production of an electrical voltage and/or current in an electrical conductor. The electrical conductor may be any type of electrical conductor such as a coil which includes an electrically conductive material that is disposed around at least one flux path component or magnetostrictive element.

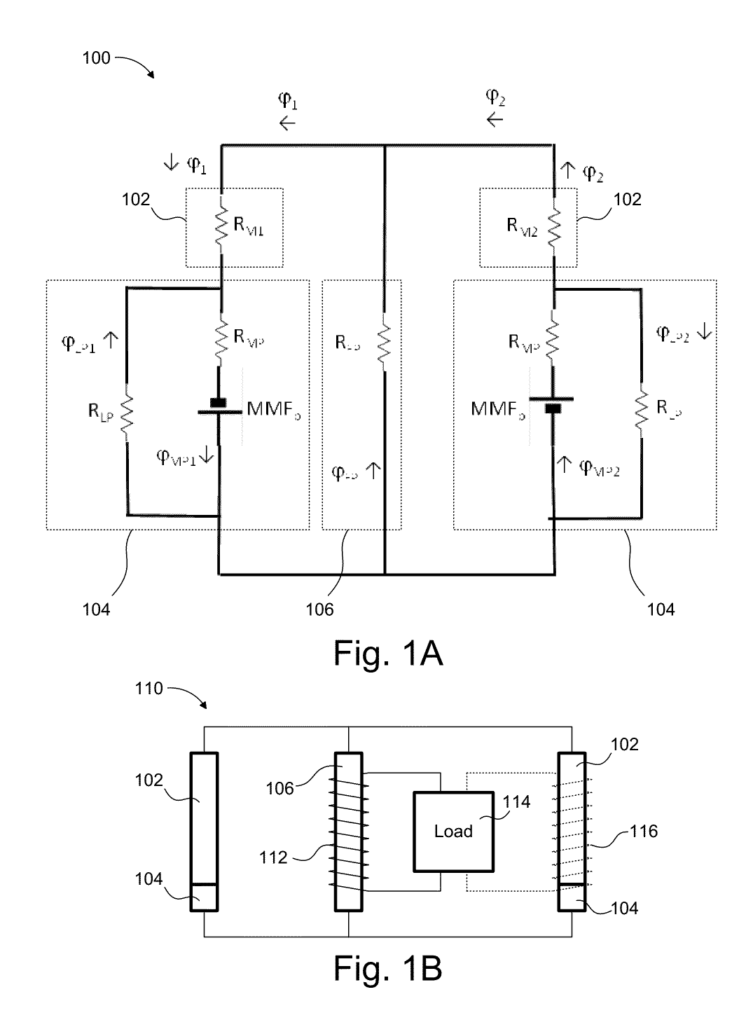

FIG. 1 illustrates a schematic diagram of one embodiment of a magnetic circuit 100 for implementation in a magnetostrictive electric power generator. This magnetic circuit 100 illustrates one example of how a device can be constructed based on one or more concepts outlined herein. The illustrated magnetic circuit 100 includes two primary flux paths 102, each having at least one associated magnet 104, and a secondary flux path 106. Reluctances and other properties of these various components are shown in the figure.

In the illustrated diagram, R_{M1} represents the magnetic reluctance of a magnetostrictive element M1 (or a group of magnetostrictive elements) in the first primary flux path 102, and R_{M2} represents the magnetic reluctance of another magnetostrictive element M2 (or a group of magnetostrictive elements) in the second primary flux path 102. MMF_{P} represents the magnetomotive force of a permanent magnet 104 (or other magnetically permeable material) in contact, or in the magnetic circuit, with the corresponding magnetostrictive element M1 or M2. R_{MP} and R_{LP} represent the internal magnetic reluctance and the internal leakage reluctance, respectively, of each permanent magnet 104 (or other magnetically permeable material). R_{FP} represents the magnetic reluctance of the secondary flux path 106.

The equations for various nodes and loops in this magnetic circuit 100 can be written as:

φ₁−φ₂−φ_{FP}=0 (1)

φ₁−φ_{MP1}+φ_{LP1}=0 (2)

φ₂−φ_{MP2}+φ_{LP2}=0 (3)

MMF_{P}−φ_{MP1}R_{MP}−φ_{LP1}R_{LP}=0 (4)

MMF_{P}−φ_{MP2}R_{MP}−φ_{LP2}R_{LP}=0 (5)

MMF_{P}−φ_{FP}R_{FP}−φ₁R_{M1}−φ_{MP1}R_{MP}=0 (6)

MMF_{P}+φ_{FP}R_{FP}−φ₂R_{M2}−φ_{MP2}R_{MP}=0 (7)

Solving these equations, we get a solution for the flux in the secondary flux path as

$${ϕ}_{FP} = \frac{{MMF}_{P} {R}_{LP} ( {R}_{M 2} - {R}_{M 1} ) ( {R}_{LP} + {R}_{MP} )}{\begin{matrix}( {R}_{M 1} {R}_{MP} + {R}_{LP} ( {R}_{M 1} + {R}_{MP} ) ) \\ ( {R}_{M 2} {R}_{MP} + {R}_{LP} ( {R}_{M 2} + {R}_{MP} ) ) + {R}_{FP} ( {R}_{LP} + {R}_{MP} ) \\ ( ( {R}_{M 1} + {R}_{M 2} ) {R}_{MP} + {R}_{LP} ( {R}_{M 1} + {R}_{M 2} + 2 {R}_{MP} ) )\end{matrix}} \qquad ( 8 )$$

The term (R_{M2}−R_{M1}) can be positive or negative depending on whether R_{M1} is less than or greater than R_{M2}. This implies that the direction of flux in the secondary flux path 106 of magnetic circuit 100 can switch as the reluctance of one of the magnetostrictive elements (e.g., rods) in the primary flux paths 102 becomes greater or lesser compared to the other. This can happen, for example, by the stress in the two magnetostrictive rods changing anti-symmetrically with time. If the magnetostrictive element M1 of the first primary flux path 102 is heavily compressed and the magnetostrictive element M2 of the second primary flux path 102 is very lightly compressed, R_{M1} will be greater than R_{M2}. At a different time, if the magnetostrictive element M2 of the second primary flux path 102 is heavily compressed and the magnetostrictive element M1 of the first primary flux path 102 is very lightly compressed, R_{M2} will be greater than R_{M1}. By changing the applied loads on the magnetostrictive elements M1 and M2 of the first and second flux paths 102 anti-symmetrically, the flux of the secondary flux path 106 can be made to switch directions continuously.

This can be visualized by considering that when one set of magnetostrictive rods in one of the primary flux paths 102 is heavily compressed, the permanent magnet 104 associated with that set of magnetostrictive rods can only drive a smaller amount of flux through the magnetostrictive rods due to the greater reluctance, while the flux driven by the magnet 104 associated with the other set of magnetostrictive rods that are lightly compressed (or stress-relieved or in tension) in the other primary flux path 102 will be significantly greater. This asymmetry results in a net flux in the secondary flux path 106. By changing R_{M1} and R_{M2} through continually varying the stress in the magnetostrictive elements M1 and M2 of the primary flux paths 102, respectively a continuously changing flux can be realized in the secondary flux path 106. By putting a coil (see FIG. 1B) around the secondary flux path 106 and/or magnetostrictive rods in the primary flux paths 102, electric power can be produced by electromagnetic induction. As explained above, forces applied to the magnetostrictive elements M1 and M2 of the primary flux paths 102 may be occur anti-symmetrically or in another opposing or asymmetrical manner.

FIG. 1B illustrates a schematic diagram of one embodiment of a magnetostrictive electric power generator system 110 using the magnetic circuit 100 of FIG. 1A. In the illustrated embodiment, a coil 112 of conductive material is wrapped around at least a portion of the secondary flux path 106. The coil 112 is also coupled to a load 114 to consumer some or all of the electricity induced in the coil from the flux changes in the secondary flux path 106. Although a single load 114 is shown, other embodiments may include any number of loads and/or any type of device capable of consuming and/or dissipating some or all of the induced electrical energy. In a further embodiment, a separate coil 116 may be wrapped around one or more of the primary flux paths 106, acting as a bias flux path, to separately generate electrical energy from the flux changes in the primary flux path 106.

In the secondary flux path 106, the choice of materials and the cross-sectional area of the secondary flux path 106 can be selected such that the flux density change achieved can be very high. For example, if an alloy with a saturation magnetization in excess of 2 Tesla can be used, the theoretical maximum flux density change that can be achieved through this approach is from +2 Tesla to −2 Tesla, or a total of 4 Tesla. This significantly exceeds the flux density produced by any magnetostrictive generator previously known. In practice, the choice of material may also be made considering other factors such as, for example, minimizing or influencing magnetic hysteresis, maximizing or influencing magnetic permeability, and maximizing or influencing electrical resistivity. Considering these factors, various iron alloys, including various grades of steel, may be appropriate choices. In some embodiments, iron alloys or steels containing one or more of Co, Mn, Al, Si may be appropriate choices. In some embodiments, the composition may contain less than 25 at % of one or more alloying elements, including one or more of one or more of Co, Mn, Al, Si. In other embodiments, the composition may contain less than 10 at % of one or more alloying elements.

In some embodiments, a primary flux path 102 and/or the secondary flux path 106 may be fabricated as a laminated component, rather than as a single machined component. This may be particularly attractive in systems where the primary flux path 102 is used as a reference flux path and is not loaded.

Additionally, using a laminated flux path component may have the benefit of reducing or minimizing eddy current losses in the system, especially for higher frequency load changes. In some embodiments, laminated components are used as magnetic flux carrying components in electromagnetic devices such as electrical generators and electric motors. The term laminated component has the same meaning here as its conventional meaning for electric generators/motors. In some embodiments, these components are fabricated by stacking and usually bonding thin sheets of magnetically conductive material either separated or bonded by electrically insulating material such as a plastic film allowing magnetic flux to be transmitted through the sheets while reducing or minimizing the possibility of eddy currents circulating through the area of the component.

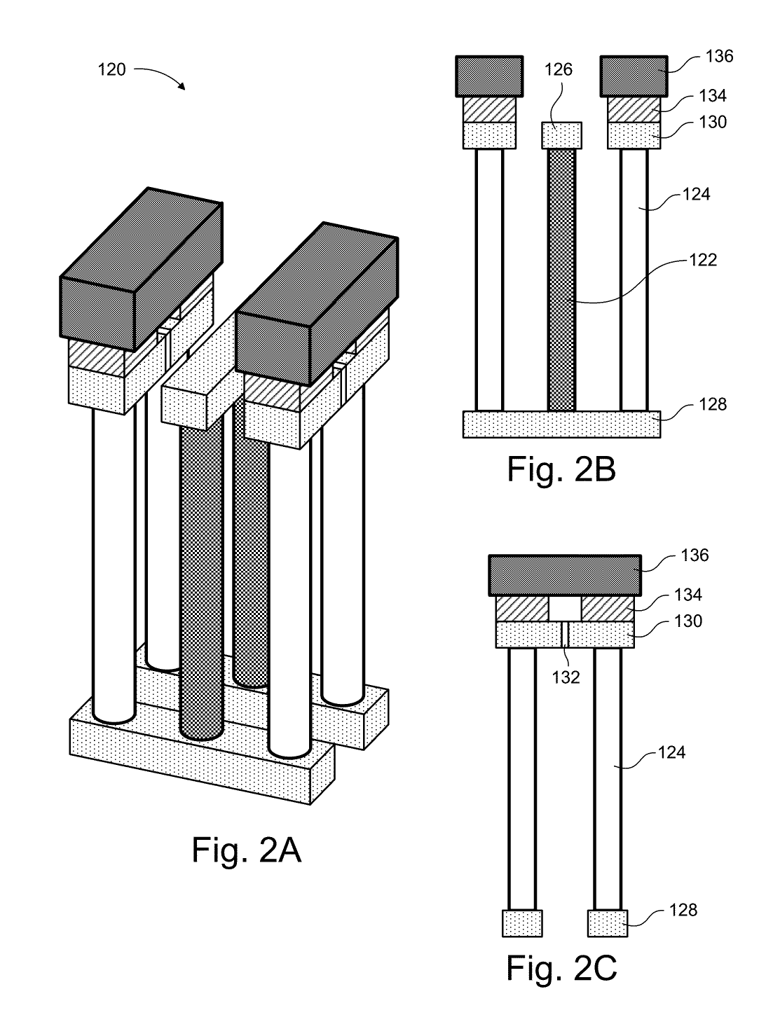

FIGS. 2A-C illustrate a schematic diagram of one embedment of a magnetostrictive generator assembly 120 with a secondary flux path 122 between two primary flux paths 124. In particular, FIG. 2A illustrates a perspective view; FIG. 2B illustrates a front view; and FIG. 2C illustrates a side view.

The illustrated magnetostrictive generator assembly 120 includes the secondary flux path 122, which is arranged with two rods and a connecting flux path component 126 across the tops of the two rods. The bottom of each rod of the secondary flux path 122 is mounted to a separate flux path component 128. Aspects of the secondary flux path 122 are viewable in FIGS. 2A and 2B.

Each of the primary flux paths 124 includes two magnetostrictive material rods. The tops of the two magnetostrictive material rods are connected by an assembly of flux path components 130 and a magnetic material spacer 132 (i.e., magnet). The magnetic material spacer 132 is viewable in FIGS. 2A and 2C. The bottom of each magnetostrictive material rod of the primary flux paths 124 is mounted to the separate flux path components 128. So each flux path component 130 is used for mounting one rod of the secondary flux path 122 and one magnetostrictive material rod from each of the primary flux paths 124.

At the top of each primary flux path 124, on top of the connecting assembly of the flux path components 130 and the magnetic material spacer 132, non-magnetic spacers 134 (e.g., aluminum) provide a connection to a loading plate 136. The loading plate 136 is configured to receive an external force, which is transferred to the magnetostrictive material rods of one or both primary flux paths 124 through the intervening materials shown and described herein. Other embodiments may include other materials, layers, or components to facilitate similar load transfer and magnetic circuitry functions as described herein.

Flux density can be made to switch directions in the secondary flux path 122 by anti-symmetrically changing, or otherwise alternating, the load(s) on the two sets of magnetostrictive rods in the primary flux paths 124. Each primary flux path 124 that experiences an external load acts as a bias flux path where flux changes originate and ultimately influence the flux characteristics in the secondary flux path 122.

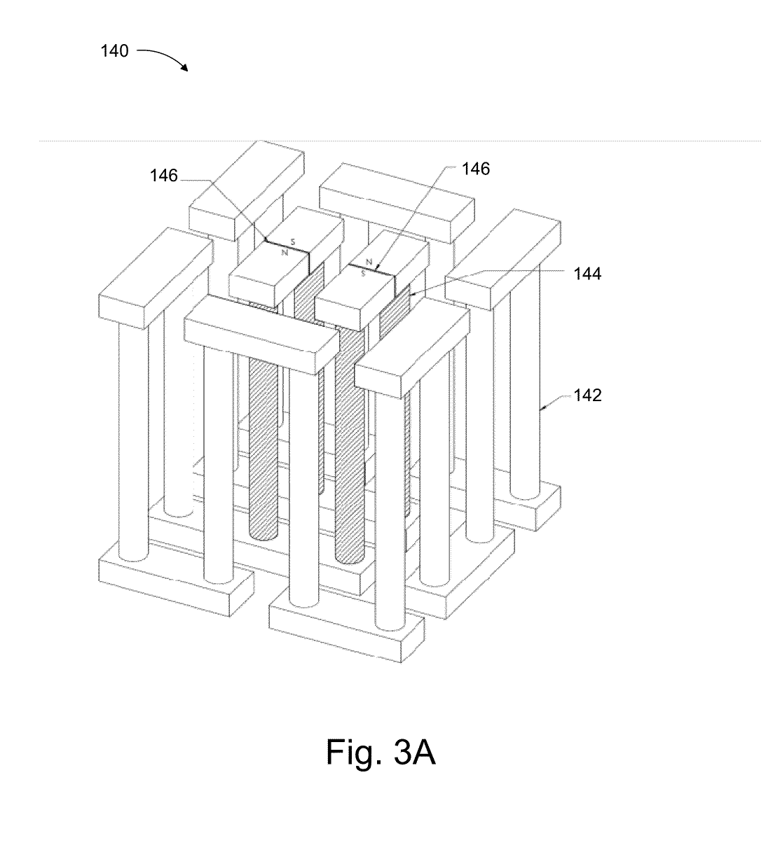

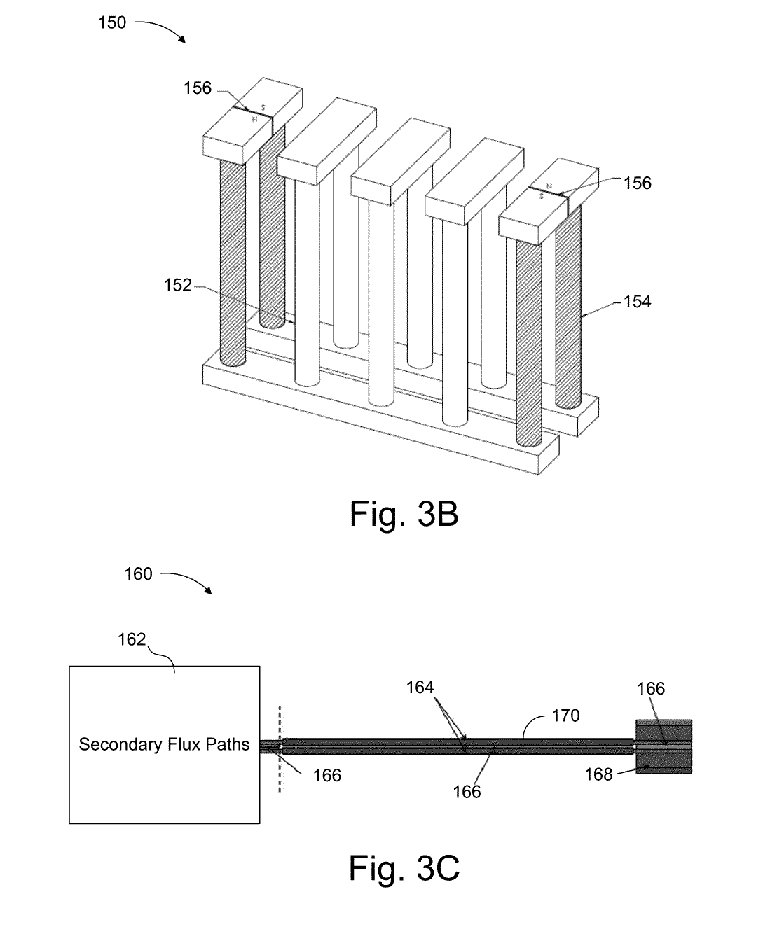

FIG. 3A illustrates another embodiment of magnetostrictive generator assembly that has a secondary flux path 142 that is much longer than the primary flux paths 144. In the illustrated embodiment, the secondary flux path 142 is not located between the primary flux paths 144. The secondary flux path 142 is located around the primary flux paths 144 with several rod pairs in series. Adjacent rods of the secondary flux path 142 are connected together at the tops and bottoms by connecting flux path components. Although particular arrangement of rods and connecting components is depicted, other embodiments may implement other shapes, sizes, and path and connection routes. There is no restriction on the relative sizes, orientations, or locations of the rods or connecting components.

By providing a longer secondary flux path 142, it may be possible to mount longer coils (not shown) around portions of the secondary flux path 142 to provide a higher power density. Additionally, a longer secondary flux path 142 also may or may not impact sensitivity of the magnetostrictive generator.

In other embodiments, other configurations of one or more secondary flux paths may be implemented. The secondary flux paths may be arranged in series or in parallel with each other. FIG. 3B illustrates another embodiment of magnetostrictive generator assembly that has multiple secondary flux paths 152 in parallel with the primary flux paths 154. Magnets 156 are mounted in the connecting components between the rods of each primary flux path 154. In this embodiment, several rod pairs of the secondary flux path 152 are coupled in parallel to the same base plates as the primary flux paths 154. In this configuration, there may be as few as two base plates for the magnetostrictive generator assembly 150. Also, although the secondary flux paths 152 are shown located between the primary flux paths 154, in other embodiments one or more of the secondary flux paths 152 may be located outside of the primary flux paths 154. So there may be virtually any orientation of the secondary flux paths 152, extending in any direction, relative to the placement of the primary flux paths 154.

FIG. 3C illustrates another embodiment of cantilevered magnetostrictive generator assembly 160 that has a secondary flux path 162 coupled to the primary flux paths 164. The primary flux paths 164 include multiple beams that extend outward from a mounting end (designated by the dashed line) to a mass assembly 168 or bluff body. One or both of the beams may include magnetostrictive material. Each beam also may have a coil 170 wrapped around it for induction of electricity depending on the movement of and forces on the magnetostrictive material. Magnetic material 166 may be included at either end or both ends of the cantilever beams.

Additional details of cantilever and other bluff body magnetostrictive generator embodiments are provided in U.S. patent application Ser. No. 13/333,173, which was filed on Dec. 21, 2011, the details of which are incorporated herein in their entirety.

In the depicted embodiment, one or more secondary flux paths 162 are coupled to the magnetostrictive rod(s) of the illustrated beam assembly. The beams serve as the primary flux paths 164, and the secondary flux paths 142 are magnetically coupled to ends of the primary flux paths 164. Although the illustrated embodiment shows coils 170 wrapped around the primary flux paths 164, in other embodiments, the coils also may be wrapped around the secondary flux paths 162. In further embodiments, the coils may be wrapped exclusively around the secondary flux paths 162.

In some embodiments, the physical properties (area, length, etc.) of the secondary flux path 162 may be chosen such that the maximum magnitude of flux density encountered during typical operation approaches magnetic saturation of at least one material used in the secondary flux path 162. Since, for a given cross-sectional area, the length of the secondary flux path 162 increases the magnetic reluctance of the secondary flux path, the length may be chosen such that the desired (typically as high as possible) flux density change may be affected in the secondary flux path 162.

Although specific geometries are depicted for the primary or secondary flux paths in the embodiments shown and described herein, in other embodiments the primary or secondary flux paths may be any physical shape, size, or geometry. For example, the primary or secondary flux paths may incorporate a single piece of magnetically conductive material, multiple pieces of magnetically conductive material and/or air gaps. The secondary flux paths may have a consistent cross-sectional shape and size (e.g., circular, square, rectangular, etc.) or may be of various cross-sectional shapes and or sizes. Additionally, in embodiments with multiple secondary flux paths, some of the secondary flux paths may be of different shapes, sizes, geometries, and/or orientations, from the other secondary flux paths. In other words, the secondary flux paths do not need to be uniform with each other in their features. Similarly, the secondary flux paths may be made of different materials having distinct magnetic properties, or may be made of a single material having substantially consistent magnetic properties. Furthermore, the primary flux paths also may vary from one another in any of the above-mentioned characteristics or other physical characteristics.

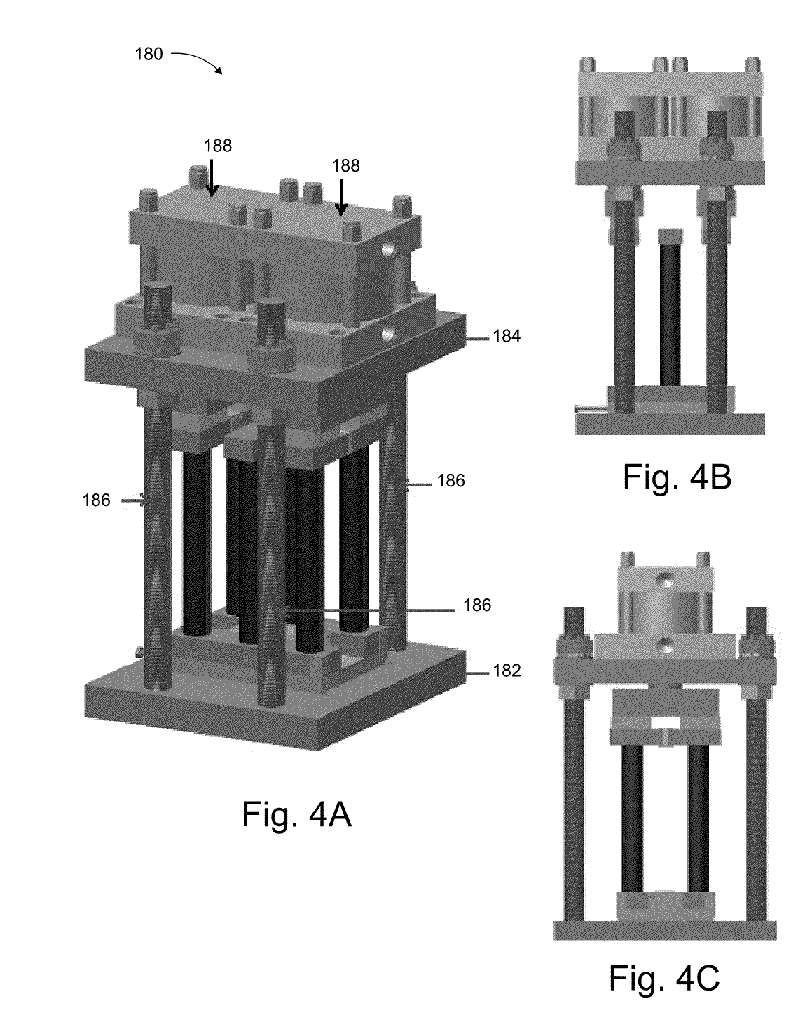

FIGS. 4A-C illustrates a schematic diagram of the magnetostrictive generator assembly of FIGS. 2A-C with one embodiment of a hydraulic load application system 180. The illustrated hydraulic loading system 180 includes a base plate 182, a top plate 184, frame rods 186, and hydraulic cylinders 188. Other embodiments of hydraulic load application systems may include other components consistent with delivering a hydraulic load to the magnetostrictive generator assembly.

Embodiments of the hydraulic load application system supply an external force to one or both of the primary flux paths of the magnetostrictive generator assembly. The forces may be symmetric, anti-symmetric, or otherwise asynchronous. In other embodiments, anti-symmetric, alternating, or other external loads applied to the primary flux paths may be applied either through the use of hydraulic pistons or other mechanical designs.

If hydraulics are used, two or more pistons may be used on the two or more sets of magnetostrictive rods of the primary flux paths. In one embodiment, as one piston applies an increasing compressive load, the other piston applies a decreasing compressive load. When the loads applied by both pistons are the same, there is no flux in the external (secondary) flux path. When the load changes from this condition, the flux lines are in one direction or the other, depending on which rod is compressed more. Although the figures illustrate one example of a practical design that allows the switching circuit to function as desired using hydraulic pistons, other embodiments may be implemented based on mechanical switching designs.

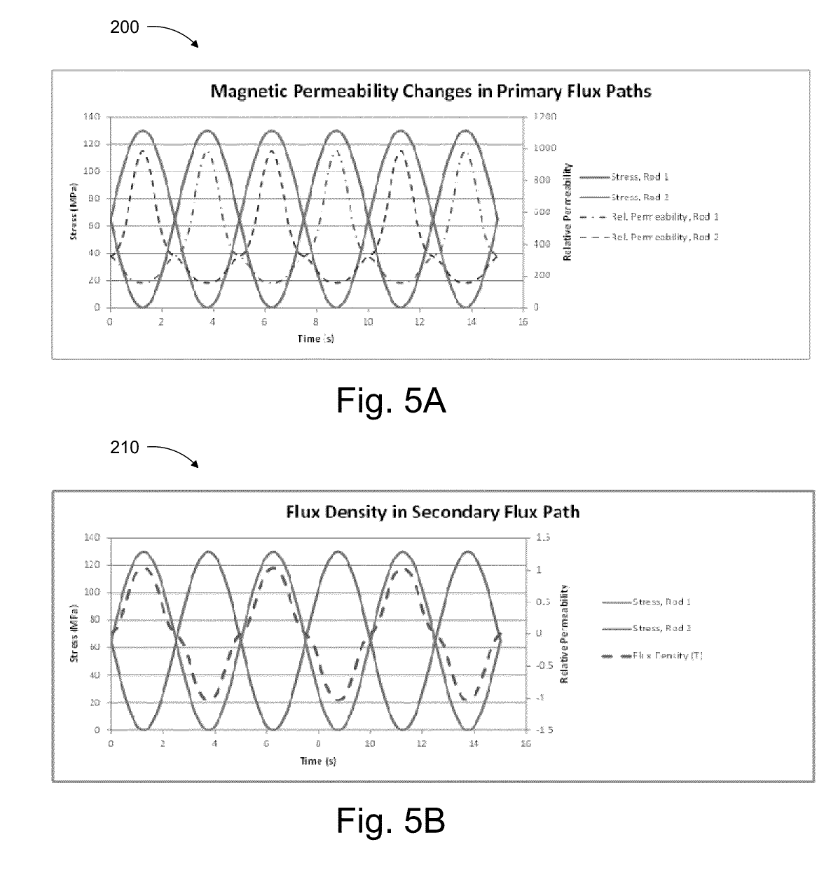

FIG. 5A illustrates schematic waveforms 200 to show stresses applied to an embodiment magnetostrictive rods. In particular, FIG. 5A shows one embodiment of the stresses applied to the magnetostrictive rods in the primary flux path from simulations of a magnetic circuit performed using LT-Spice software, and the corresponding change in relative permeability in the rods. FIG. 5B illustrates schematic waveforms 210 to show the flux density in the secondary flux path (dashed line) changing from a positive to a negative value, for a total change of approximately 2 Tesla.

In some embodiments, one or more components of a frame, in which the magnetostrictive generator is mounted, may be used as part of the primary or secondary flux paths. This may have the benefit of reducing the overall weight of the structure needed to produce a target power, thereby increasing the overall power density of the device.

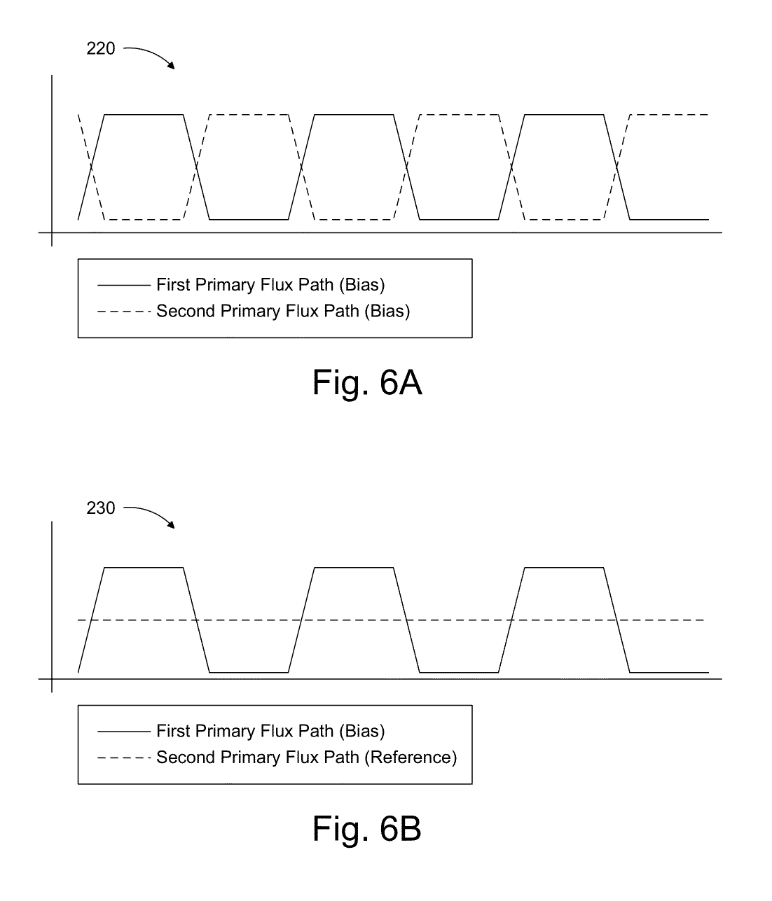

FIGS. 6A and 6B illustrate alternative embodiments of schematic waveforms 220 and 230 to depict relative flux changes in primary flux paths. It should be noted that the waveforms provided in these figures are merely illustrative and are not limiting in the type, shape, duration, or any other waveform features of actual flux changes that might be produced within a particular embodiment of a magnetostrictive generator.

In FIG. 6A, both the first and second primary flux paths are implemented as bias flux paths. So both of the primary flux paths experience external load changes, which result in flux changes within the primary flux paths. In the depicted embodiment, the flux changes are shown opposite one another, which would result from opposite load changes applied to the separate primary flux paths.

In FIG. 6B, the first primary flux path is implemented as a bias flux path, while the second primary flux path is implemented in a reference flux path. The reference flux path has physical properties that maintain a relatively static magnetic flux over time and/or over a range of external loads. In one embodiment, the bias flux path is made of another material (or materials) that has a range of flux properties over a range of external load conditions. The bias and reference flux paths may be made of respective materials that allow the flux properties of the reference flux path to remain within the range of flux properties of the bias flux path. This ensures that there is a relative difference, both positive and negative, for any flux changes experienced on a separate secondary flux path coupled to the primary flux paths.

In other embodiments, the reference flux path may have static flux properties that are always lower than or higher than the range of flux properties of the corresponding bias flux path.

In some embodiments, multiple coupled flux paths also may use pre-stressed (e.g., pre-compressed) magnetostrictive materials. In some embodiments, the primary and secondary flux paths may be configured such that all the loading is mechanical (i.e., without the use of hydraulics). This may be done by pre-compressing one set of rods such that when a load is applied, one set of magnetostrictive rods are relieving this pre-compression while the other set is increasing in compression. Various embodiments of how this might be achieved are described in application number U.S. patent application Ser. No. 18/213,390, which was filed on Feb. 14, 2014, and claims priority to U.S. Provisional Application No. 61/764,732, filed on Feb. 14, 2013, and U.S. Provisional Application No. 61/809,155, filed on Apr. 5, 2013, each of which is incorporated by reference herein. One or more secondary flux path connected to components that are magnetically linked with one or more primary flux paths described in this embodiment will function in a similar manner to the embodiments described herein.

Embodiments described herein include a method and device that incorporate at least one magnetostrictive element that comprises at least one magnetostrictive material. Changes in stress in at least one magnetostrictive material result in a change in magnetic flux in at least one other component that is magnetically linked to the at least one magnetostrictive material. The magnetostrictive material may include any material which experiences a measurable change in at least one magnetic property when subjected to a change in stress. In some embodiments, the magnetic property is magnetic permeability. As used herein, a measurable change is a change in relative permeability of at least 1, and in some embodiments at least 100, through the application of a stress of at least 1 MPa, and typically 10-200 MPa.

In some embodiments, the change in flux in at least one magnetostrictive element results in a change in direction of the flux in at least one other component that is magnetically linked to the magnetostrictive material. In some embodiments, the change in flux in at least two magnetostrictive elements results in a change in direction of the flux in at least one other component that is magnetically linked to at least one of the two magnetostrictive materials.

Although many embodiments described herein are capable of generating electrical power from magnetostrictive elements, embodiments of secondary flux paths may be implemented in any type of magnetostrictive circuit, including generators, sensors, and other devices. The principles and embodiments described herein which facilitate improved power density may be applied to other forms of magnetostrictive devices.

Additionally, in some embodiments, actuators or other devices that use magnetostriction to generate mechanical deflection in response to applied electrical input (as opposed to reverse magnetostriction) also may benefit from implementations with a secondary flux path. In these embodiments, some or all of the electrical input applied to the magnetostrictive element may be applied at the secondary flux path.

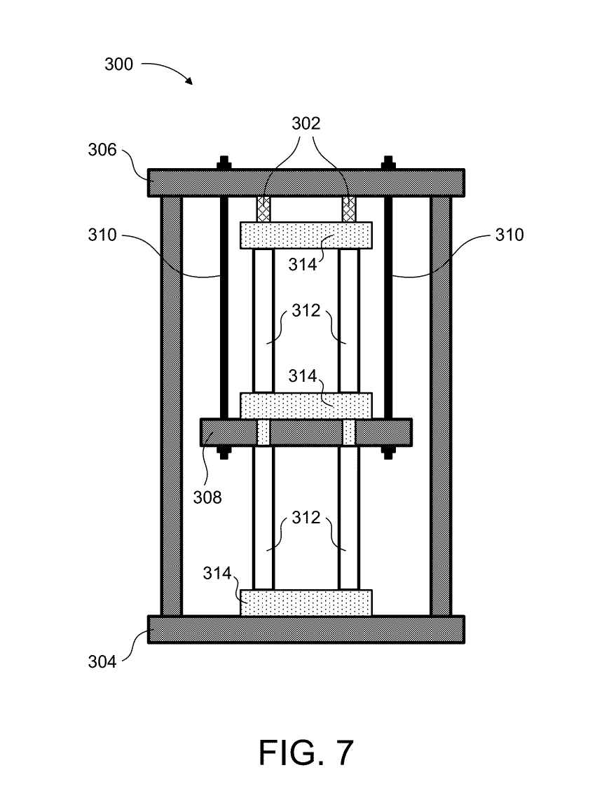

Additionally, some embodiments utilize stiffness adjustors in conjunction with pre-stressed magnetostrictive materials. FIG. 7 illustrates a schematic diagram of one embodiment of magnetostrictive generator assembly 300 that includes stiffness adjusters 302 within a pre-compression zone. The illustrated embodiments include a frame assembly with a bottom plate 304 and a top plate 306. Side frame members also may be included. Within the frame, a pre-compression zone is created between the top plate 306 and a middle plate 308. The middle plate 308 is secure to the top plate 306 by two or more pre-compression bolts 310 or other similar fasteners. The bolts are tightened and secured to maintain a constant pressure on the internal components between the middle plate 308 and the top plate 106.

The internal components between the middle plate 308 and the top plate 106 include a pair of magnetostrictive elements 312 (i.e. rods) with flux path components 314 at both ends of the magnetostrictive elements 312. In the depicted embodiment, the stiffness adjusters 302 are interposed between the top flux path component 314 and the top plate 306 of the frame. Below the middle plate 308 are additional magnetostrictive elements 312 and one or more flux path components 314. Additionally, flux path components may pass through or around the middle plate 308 to couple the components above and below the middle plate 308. In some embodiments, there use of multiple flux paths allows for higher flux density.

The upper magnetostrictive rods 312 are pre-compressed by the pre-compression bolts 310. By pre-compressing the magnetostrictive rods 312, even when a tensile force is exerted upon the top plate 306 and the bottom plate 304 of the frame, the pre-compressed magnetostrictive rods 312 may cycle through only changes in compressive forces. In this way, the use of the pre-compression bolts 310 may allow the magnetostrictive rods 312 to not be subjected to tensile loads.

The stiffness adjusters 302 may be made from many different materials each with a different stiffness. The stiffness, or resistance to deformation in response to a load, may also vary in each stiffness adjuster 302. The size, shape, and location of each stiffness adjuster 302 may vary, and the overall number of stiffness adjusters 302 may vary as well. In the illustrated embodiment, the stiffness adjusters 302 are pre-compressed along with the upper magnetostrictive rods 312. Depending on the material used for the stiffness adjusters 312, a tensile load on the stiffness adjusters 312 may lead to a potential early failure. The pre-compression may eliminate the application of tensile stresses to the stiffness adjusters 302 and prolong the overall life of the device.

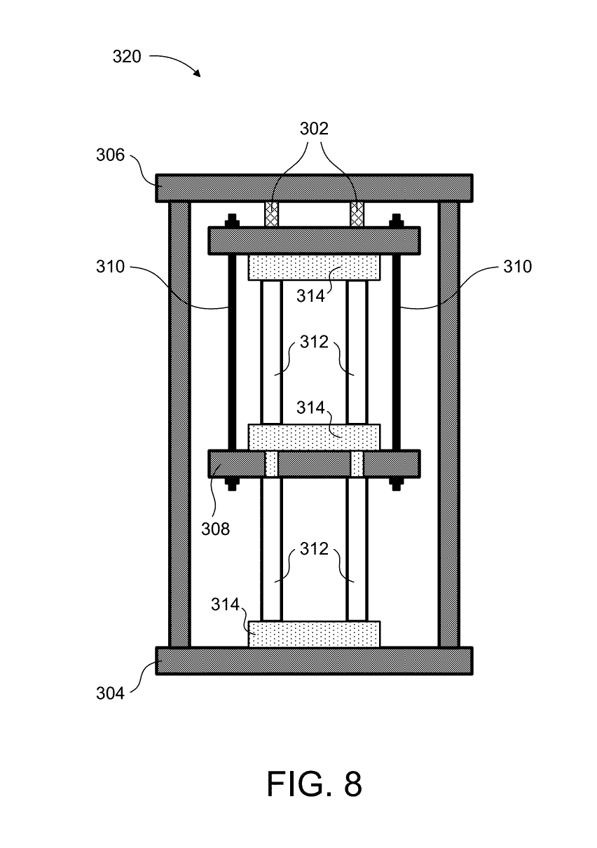

FIG. 8 illustrates a schematic diagram of another embodiment of magnetostrictive generator assembly 320 that includes stiffness adjusters 302 outside of a pre-compression zone.

In contrast to the embodiment shown in FIG. 7 and described above, the stiffness adjusters 302 in the embodiment of FIG. 8 are not pre-compressed and may be subject to tensile stresses. The stiffness adjusters 302 may be made from many different materials each with a different stiffness. The stiffness, or resistance to deformation in response to a load, may also vary in each stiffness adjuster 302. The size, shape, and location of each stiffness adjuster 302 may vary, and the overall number of stiffness adjusters 302 may vary as well.

The embodiments shown in FIGS. 7 and 8 include multiple flux paths. Multiple flux paths allow for higher flux density. In some embodiments, providing a second path allows offsetting of one flux path from a second flux path. In some embodiments, when the strains of the magnetostrictive rods in one flux path may differ from the strains of the magnetostrictive rods in a second flux path by virtue of varying the effective stiffness of individual components by utilizing the stiffness adjusters 302.

The alignment of the stiffness adjusters 312 and the magnetostrictive rods 312 may vary. In some embodiments, the stiffness adjusters 302 are aligned with the magnetostrictive rods 302. In some embodiments, the stiffness adjusters 302 are not aligned with the magnetostrictive rods 312, in one or more dimensions. The number of stiffness adjusters 302 may vary. In some embodiments, the number of stiffness adjusters 302 is equal to the number of magnetostrictive rods 312 within a flux path. For example, in FIG. 7, two stiffness adjusters 302 are shown directly above two magnetostrictive rods 312. In some embodiments, the number of stiffness adjusters 302 is greater than the number of magnetostrictive rods 312. In some embodiments, the number of stiffness adjusters 302 is less than the number of magnetostrictive rods 312.

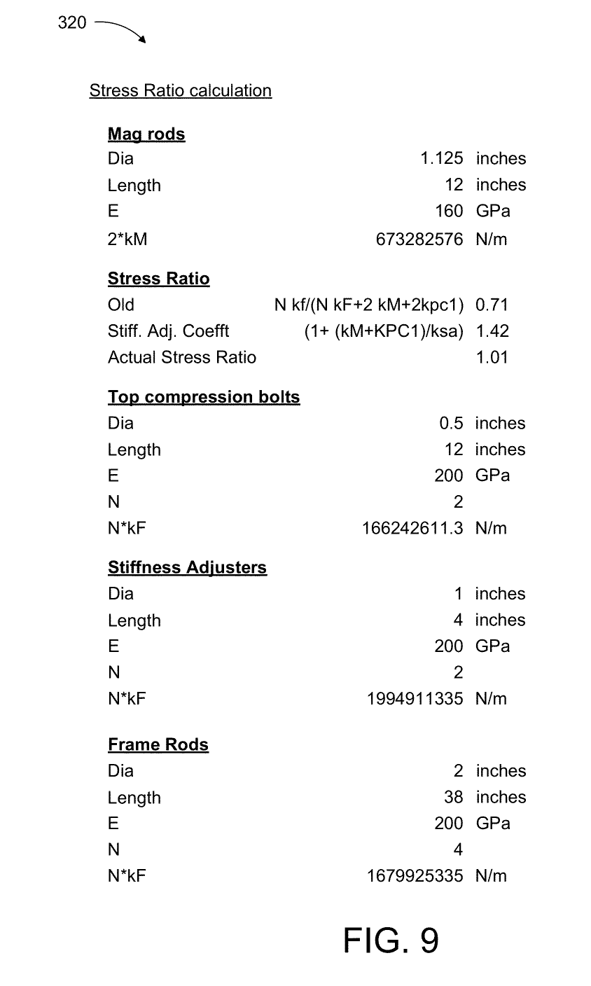

FIG. 9 depicts results from a stress ratio calculation using stiffness adjusters showing the changes in stress ratio with the addition of a stiffness adjuster.

In the above description, specific details of various embodiments are provided. However, some embodiments may be practiced with less than all of these specific details. In other instances, certain methods, procedures, components, structures, and/or functions are described in no more detail than to enable the various embodiments of the invention, for the sake of brevity and clarity.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. An apparatus comprising:
at least two primary flux paths, wherein at least one of the primary flux paths comprises a bias flux path configured to exhibit a change in a flux property in response to a change in an external load applied to the bias flux path; and
a secondary flux path magnetically coupled to the primary flux paths, wherein the secondary flux path is configured to experience alternating flux directions in response to the change in the flux property of the bias flux path.

2. The apparatus of claim 1, wherein the bias flux path comprises a magnetostrictive material to manifest a change in magnetic flux in response to a change in stress or strain.

3. The apparatus of claim 1, further comprising at least one permanent magnet to provide a source of magnetomotive force within the bias flux path.

4. The apparatus of claim 1, further comprising an electrical conductor in proximity to at least one flux path of the primary and secondary flux paths, wherein the electrical conductor is configured to experience a change in electrical properties in response to the change in flux properties of the at least one flux path.

5. The apparatus of claim 4, wherein the electrical conductor further comprises a coil of conductive material wrapped around at least a portion of the secondary flux path to conduct induced electrical energy in response to the alternating flux directions in the secondary flux path.

6. The apparatus of claim 4, wherein the electrical conductor further comprises a coil of conductive material wrapped around at least a portion of one of the primary flux paths to conduct induced electrical energy in response to the change in the flux property of the corresponding primary flux path.

7. The apparatus of claim 1, wherein the primary flux paths further comprise at least one reference flux path configured to exhibit unchanging flux properties during the change in the external load applied to the bias flux path.

8. The apparatus of claim 1, wherein the magnetostrictive device is an electrical generator or energy harvester.

9. The apparatus of claim 1, wherein the secondary flux path is located between at least two of the primary flux paths.

10. The apparatus of claim 1, wherein the secondary flux has a length that is greater than a length of any of the primary flux paths.

11. The apparatus of claim 1, wherein the secondary flux has a length that is equal to a length of at least one of the primary flux paths.

12. The apparatus of claim 1, further comprising two common flux path components to magnetically connect the primary and secondary flux paths.

13. The apparatus of claim 1, wherein a first flux path component is coupled to one side of each of the primary and secondary flux paths, and a second flux path component is coupled to another side of each of the primary and secondary flux paths.

14. A device for generating electrical energy from mechanical motion, the device comprising:
a magnetostrictive generator assembly configured to generate electricity from magnetostriction based on changing applied stresses to magnetostrictive rods, wherein the magnetostrictive rods are pre-compressed by compression plates fastened together by compression bolts, wherein the magnetostrictive generator assembly further comprises at least one stiffness adjuster placed in series with at least one of the magnetostrictive rods.

15. The device for generating electrical energy from mechanical motion of claim 14, wherein the at least one stiffness adjuster is pre-compressed by the compression plates fastened together by the compression bolts.

16. The device for generating electrical energy from mechanical motion of claim 14, wherein the at least one stiffness adjuster is not pre-compressed by the compression plates fastened together by the compression bolts.

17. The device for generating electrical energy from mechanical motion of claim 14, wherein the at least one stiffness adjuster is aligned with the magnetostrictive rods.

18. The device for generating electrical energy from mechanical motion of claim 17, wherein a longitudinal axis of the at least one stiffness adjuster is aligned with a longitudinal axis of one of the magnetostrictive rods.

19. The device for generating electrical energy from mechanical motion of claim 14, wherein the number of stiffness adjusters is greater than the number of magnetostrictive rods.

20. The device for generating electrical energy from mechanical motion of claim 14, wherein the number of stiffness adjusters is less than the number of magnetostrictive rods.
